(19) United States
(12) Patent Application Publication
(10) Pub. No.: US 2009/0229661 A1
(43) Pub. Date: Sep. 17, 2009

(54) High Efficiency Solar Cells

(75) Inventor: Mark G. Mortenson, North East, MD (US)

Correspondence Address: MARK G. MORTENSON, POST OFFICE BOX 310, NORTH EAST, MD, 21901-0310, US

(73) Assignee: GR Intellectual Reserve, LLC

(21) Appl. No.: 12/400,915

(22) Filed: Mar. 10, 2009

Related U.S. Application Data
(62) Division of application No. 10/535,652, filed on Jan. 30, 2006, now abandoned.
(60) Provisional application No. 60/428,119, filed on Nov. 20, 2002.

(51) Int. Cl. H01L 31/00

(52) U.S. Cl. 136/258; 136/252

(57) ABSTRACT

The present invention relates to improvements in solar cell and solar panel photovoltaic materials which cause the solar cells/panels to operate more efficiently. In particular, the present invention focuses primarily on matching or modifying particular incident light energies (e.g., solar energies) within the photoreactive portion of the solar spectrum to predetermined energy levels in a solar cell photovoltaic substrate material (e.g., a semiconductor material) required to excite, for example, electrons in at least a portion of the substrate material in a desirable manner (e.g., to cause desirable movement of electrons to result in output amperages previously unobtainable). In this regard, for example, energy levels of incident light within the optical or visible light portion of the solar spectrum (i.e., the photoreactive portion of the solar spectrum) and thus, corresponding particular wavelengths or frequencies of incident light, can be at least partially matched with various desirable energy levels (e.g., electron band gap energy levels) in a substrate material by filtering out at least a portion of certain undesirable incident light from the photoreactive portion of the solar spectrum that comes into contact with at least a portion of a surface of a solar cell photovoltaic substrate material; and/or modifying at least a portion of a solar cell photovoltaic substrate material such that the solar cell substrate material interacts more favorably with particular desirable frequencies of incident light in the photoreactive portion of the solar spectrum; and/or modifying particular undesirable light energies within the band of optical or visible light wavelengths to which the photovoltaic substrate material is sensitive prior to such undesirable light energies becoming incident on the photovoltaic substrate material to render such light energies more desirable for interactions with the photovoltaic substrate material.

The present application is a divisional of U.S. Application No. 10/535,652, hereby incorporated by reference, which entered the U.S. national phase on Jan. 30, 2006, from PCT/US03/37198. The International Application, PCT/USO3/37198, claims priority to U.S. Provisional Application No. 60/428,119 and the priority date of the International Application is Nov. 20, 2002.

### FIELD OF THE INVENTION

The present invention relates to improvements in solar cell and solar panel photovoltaic materials which cause the solar cells/panels to operate more efficiently. In particular, the present invention focuses primarily on matching or modifying particular incident light energies (e.g., solar energies) within the photoreactive portion of the solar spectrum to predetermined energy levels in a solar cell photovoltaic substrate material (e.g., a semiconductor material) required to excite, for example, electrons in at least a portion of the substrate material in a desirable manner (e.g., to cause desirable movement of electrons to result in output amperages previously unobtainable). In this regard, for example, energy levels of incident light within the optical or visible light portion of the solar spectrum (i.e., the photoreactive portion of the solar spectrum) and thus, corresponding particular wavelengths or frequencies of incident light, can be at least partially matched with various desirable energy levels (e.g., electron band gap energy levels) in a substrate material by filtering out at least a portion of certain undesirable incident light from the photoreactive portion of the solar spectrum that comes into contact with at least a portion of a surface of a solar cell photovoltaic substrate material; and/or modifying at least a portion of a solar cell photovoltaic substrate material such that the solar cell substrate material interacts more favorably with particular desirable frequencies of incident light in the photoreactive portion of the solar spectrum; and/or modifying particular undesirable light energies within the band of optical or visible light wavelengths to which the photovoltaic substrate material is sensitive prior to such undesirable light energies becoming incident on the photovoltaic substrate material to render such light energies more desirable for interactions with the photovoltaic substrate material.

### BACKGROUND OF THE INVENTION

For many years, effort has been made to utilize the energy from the sun to produce electricity. It is well known that on a clear day the sun provides approximately one thousand watts of energy per square meter almost everywhere on the planet's surface. The historical intention has been to collect this energy by using, for example, an appropriate solar semiconductor device and utilizing the collected energy to produce power by the creation of a suitable voltage and to maximize amperage which is represented by the flow of electrons. However, to date, many photovoltaic cells typically have an overall efficiency as low as about 10-25%. In this regard, that means that when one thousand watts of energy are incident on a square meter of a typical photovoltaic cell, somewhere between about 100 and 250 watts of output energy power typically results. This typical low efficiency in solar cells has been a significant reason for the solar cell industry not growing faster. For example, it is relatively expensive to manufacture those semiconductor materials currently utilized for solar cells (e.g., crystalline silicon, amorphous silicon, cadmium sulfide, etc.) into solar panels (e.g., typically, a plurality of combined solar cells electrically connected together) which includes the high costs of forming the solar cell substrate materials themselves, the cost of modifying the substrate materials so that they can become photovoltaic (e.g., doping the semiconductor substrate material to create substrate p/n junctions, etc.), the placement of electron collecting grids on surfaces of the solar cells, manufacturing the solar cells into solar panels, etc.

For example, in regard to a first example of utilizing crystalline silicon, one traditional approach for manufacturing solar cells has included converting scrap silicon wafers from the semiconductor industry into solar cells by known techniques which include etching of the solar cells and subsequent processing of the silicon wafers so that they can function as solar cells. A second technique includes creating relatively thin layers of crystalline and/or amorphous silicon upon an appropriate substrate and then utilizing somewhat similar subsequent processing steps to those discussed above to result in a solar cell/solar panel. In each of these two general approaches to obtaining a suitable photovoltaic substrate, the semiconducting nature of the silicon is utilized so that when incident light strikes a doped (e.g., a p-type and/or an n-type doped material) silicon solar cell substrate material, the incident light can be at least partially absorbed (e.g., a photon of light corresponding to a certain amount of energy can be absorbed) into the silicon semiconductor. The absorbed photon results in a transfer of energy to the semiconductor and the transferred energy can result in electron flow in a circuit (e.g., along with, for example, paired electron holes flowing in an opposite direction). A flow of electrons is typically referred to as a current. Solar cells of this type also usually will have a particular voltage associated with the produced current. By placing or positioning appropriate metal collecting electrodes on, for example, the top and bottom of the silicon semiconductor material, the electrons produced can be extracted from the cell as current which can be used, for example, to power an appropriate external device and/or charge a battery. However, this entire process has historically been relatively inefficient, making the solar cell industry less than ideal.

Further, attempts have been made to prevent certain large portions or bands of the solar spectrum outside of the photoreactive portion thereof from being incident on solar cells. In particular, various known techniques attempt to block entire portions or bands of the solar spectrum that are typically regarded as being above and/or below the photoreactive portion of the solar system (e.g., above and/or below the visible light or optical portions of the solar spectrum to which the photovoltaic substrate is favorably sensitive). For example, these techniques attempt to minimize undesirable interactions of the solar spectrum with the solar cells which include minimizing undesirable heating from the infrared portion of the solar spectrum and minimizing undesirable physical degradation from the ultraviolet portion of the solar spectrum.

Accordingly, there has been a long felt need to enhance the efficiency of solar cells so that the cost of electricity produced by the solar cell approach can be reduced and thus assist in making a meaningful impact on the world power supply by, for example, decreasing the world's dependency on fossil fuels and/or nuclear energy. The present invention satisfies this long felt need by a novel, simple and reliable approach.

### SUMMARY OF THE INVENTION

The present invention has been developed to overcome certain shortcomings of the prior art photovoltaic materials as well as those techniques used for the manufacture of numerous compositions of solar cells/solar panels.

It is an object of the invention to produce solar cells out of various known photovoltaic substrate materials which, in some cases, can be caused to have higher efficiencies without significantly modifying, if at all modifying, such substrate materials, relative to known substrate materials used in solar cells.

It is an object of the invention to apply the techniques and methodology of the invention to at least the photovoltaic substrate materials which include, but are not limited to, crystalline silicon, amorphous silicon, single crystal silicon, cadmium sulfide, gallium arsenide, GaAs/Ge, GaInP₂/GaAs/Ge, copper-indium diselinide, GaInNAs, GaSb, In GaAs, SiGe, TiO₂, AlGaAs, CuInS₂, Fullerene C₆₀ and carbonaceous thin films.

Another object of the invention is to limit or restrict certain undesirable incident wavelengths of light (and thus certain frequencies and energy levels) from becoming incident upon a solar cell photovoltaic substrate.

It is another object of the invention to limit or restrict (i.e., minimize) certain destructively interfering (or at least partially destructively interfering) incident wavelengths of light within the photoreactive portion of the solar spectrum from becoming incident upon a solar cell photovoltaic substrate so as to maximize the incidence of constructively interfering (or at least partially constructively interfering) incident wavelengths which, for example, substantially match those wavelengths (e.g., amounts of energy) which cause desirable interactions to occur between the incident light and the solar cell substrate (e.g., excite electrons from a substrate into an appropriate energy collection system on the substrate (e.g., a conductive grid), to produce desirable electrical current). Moreover, the incident light energy can be converted to desirable atomic or molecular energies (e.g., electronic) and thus, for example, further energize the electrons to assist in the production of electrical power.

It is an object of the invention to determine which particular energies (and thus which particular wavelengths or frequencies) of incident light, within the photoreactive portion of the solar spectrum, are required for any desired solar cell photovoltaic substrate so as to permit predominantly desirable interactions to occur. Desirable interactions include, for example, electrons being excited from one energy level to another to result in current; and providing energy to the electrons which can assist in promoting the electrons to a conduction band to result in current. After determining which energies (and thus which wavelengths or frequencies) are desirable, the invention then substantially restricts the wavelengths or frequencies of undesirable light which are incident upon said substrate, said restricting occurring by utilizing an appropriate filtering technique or light modifying (e.g., shifting, refracting, etc.) technique, and thus maximizing those desirable energies of light which contact or are incident upon a solar cell substrate.

It is another object of the invention to restrict and/or modify the wavelengths of light within the photoreactive portion of the solar spectrum which are incident upon an appropriate solar cell substrate by utilizing at least one external means for modifying incident sunlight (e.g., a filter or a combination of external filters, a light refracting means, and/or a light reflecting means, etc.), which maximize(s) those desired wavelengths to be incident upon a solar cell photovoltaic substrate. Such external means include filters, or combinations of external filters, which can be incorporated into an original manufacturing process or can be later added (e.g., as a coating) as, for example, a retrofitting step to existing solar cells or solar panels.

It is another object of the invention to provide at least one filter for filtering out certain wavelengths of undesirable incident light within the photoreactive portion of the solar spectrum by providing a particular covering material in a solar cell which functions as a filter. In this regard, an appropriate covering material can be, for example, suitable polymer material(s) (including certain monomer(s) and/or oligomer(s)), or suitable glass(es), suitable coatings, and/or combinations of the same.

It is an object of the invention to provide a glass cover material which is capable of filtering, refracting and/or reflecting out as many undesirable wavelengths of incident light as possible within the photoreactive portion of the solar spectrum and thus maximizing the incidences of those wavelengths of light which desirably interact with a solar cell photovoltaic substrate material after passing through such a cover material.

To achieve all of the foregoing objects and advantages, and to overcome the disadvantages of the prior art solar cell and solar panel designs, the present invention utilizes a number of novel approaches.

Typical photovoltaic materials convert sunlight directly into electricity. Photovoltaic cells typically utilize materials known as semiconductors such as crystalline silicon, amorphous silicon, single crystal silicon, cadmium sulfide, gallium arsenide, etc., as a substrate or active material in the solar cell. Of these materials, crystalline silicon is currently one of the most commonly used. When sunlight strikes (i.e., is incident upon) a semiconductor material, it is known that certain energy units within sunlight, known as, and referred to as, photons, can be absorbed into the semiconductor material. This typically results in some portion of the energy of incident sunlight being transferred to the semiconductor material. This transfer of energy can cause, for example, electrons to be excited from their ground state into one or more excited states which permits such electrons, in certain cases, to flow somewhat freely within at least a portion of the semiconductor material (e.g., within a conductor or conduction band in the semiconductor material). These photovoltaic materials or cells also have at least one electric field which tends to force electrons to flow in a particular direction, such electrons having been created by the absorption of light energy (i.e., photons) into the semiconductor material. The flow of electrons is typically regarded and referred to as a current. By placing appropriate electrodes (e.g., one or more metal grids) on the front and back side of a photovoltaic cell, the flow of electrons can generate a current which can be used to drive electric motors, charge batteries, etc. It is the flow of electrons or current, combined with the voltage produced by the cell (e.g., which is a direct result of any built-in electric field or fields), which defines the total output or power that a solar cell, or group of solar cells in a panel or array, can produce.

The following discussion places particular emphasis on crystalline silicon, however, such discussion applies in a parallel manner to other photovoltaic materials as well. An atom of silicon is known to have 14 electrons in three different shells. The first two of these shells closest to the nucleus are regarded as being completely filled with electrons. However, the outer shell is regarded as being only half full and contains only four electrons. This is what makes crystalline silicon, when appropriately doped, a good semiconductor material and thus useful as a solar cell substrate material. In this regard, an individual silicon atom is considered to be driven to attempt to fill its outermost shell with eight electrons. In order to fill its outermost shell, the silicon atom is thought to need to share electrons with, for example, four of its neighboring silicon atoms. This attempt to share electrons with neighboring silicon atoms is essentially what forms the crystalline structure of silicon and this structure is important to the formation of this type of photovoltaic cell.

In most cases, silicon desirably includes dopants which are added to the crystalline structure to cause the silicon to work as a better semiconductor. Traditional dopants that have been historically used in the manufacture of crystalline silicon semiconductor materials include boron, phosphorous, indium, etc., the particular dopant(s) being chosen to result in desired p-type or n-type characteristics of at least a portion of a semiconductor. A more complete list of dopants than those listed above that have been used with a variety of different photovoltaic materials include, but are not limited to, germanium, beryllium, magnesium, selenium, cadmium, zinc, mercury, oxygen, chlorine, iodine and organometallic dyes (e.g., Rv(SCN)₂C₂). The purpose of these dopants is to cause, for example, the silicon to function as a better semiconductor material. By utilizing suitable dopants, the amount of energy required to be input into, for example, a silicon semiconductor to produce or promote electrons to flow is reduced significantly relative to an undoped silicon semiconductor material because in doped silicon, the electrons are not bound in a chemical bond in the same way that undoped silicon electrons are. It is desirable to have present in different portions of a silicon-based solar cell, each of an n-type behavior and a p-type behavior. For example, phosphorous can be added as a dopant to result in an n-type semiconductor portions of a silicon material and boron can be added to another portion of a semiconductor material to result in a p-type portion in a silicon semiconductor material. N-type doped materials are typically associated with the letter “n” because such materials have the presence of free electrons (i.e., n=negative); whereas p-type materials are typically associated with the letter “p” because such materials have free holes (i.e., the opposite of electrons and p=positive). The concept of holes is viewed as being important in a solar cell semiconductor material because holes are thought to be the equivalent to the absence of electrons which carry a positive charge in an opposite direction from the electron flow and are thought to move around like electrons.

Accordingly, when both p-type and n-type portions or materials are combined into a single material, at least one electric field will form due to the n-type and p-type portions of silicon being in contact with each other. In particular, free electrons on the n-side of the semiconductor recognize the presence of holes on the p-side of the semiconductor and attempt to fill in these holes by moving there. For example, in the junction between n-type and p-type portions or sections within a semiconductor material, there is a mixture of holes and electrons which reach equilibrium and thus create at least one electric field separating the two sides. This field actually functions as a diode which permits (e.g., in some cases even pushes) electrons to flow from the p-side to the n-side (e.g., but, typically, not the other way around).

Accordingly, when photons of light become incident upon the semiconductor material, the photons of light contain a certain amount of energy “E”. This amount of energy “E” is equal to Planck's constant “h” multiplied by the frequency of the light. In this regard, the well-known relationship is as follows:

E=hσ Equation 1

These photons of a particular energy, and thus of a particular wavelength and frequency, are capable of transferring energy to electrons in the semiconductor material (e.g., promoting electrons from lower energy states into, for example, the conduction band) as well as being capable of creating holes. If the electrons and/or holes are created close enough to the electric field, or if they can wander within a range of influence of such field, the field will typically send an electron to the n-side of the semiconductor and a hole to the p-side of the semiconductor. This movement of electrons and holes will result in further disruption of the electrical neutrality and if an external collection system (e.g., electrical grid) is provided, electrons will flow into and through this grid to their original side (i.e., the p-side) to unite with corresponding holes that the electric field has also sent there. This flow of electrons provides the current, as well as the electric field(s), resulting in a voltage. When both current and voltage are present, power can be created in, for example, an external device.

Traditional photovoltaic theory recognizes that incident sunlight is comprised of a number of different wavelengths of light (e.g., infrared, visible, ultraviolet, etc.) and thus includes a virtual continuum of different energies, as well as a virtual continuum of different frequencies, most all of which energies/wavelengths/frequencies (e.g., especially in the range of about 200 nm to about 1200 nm wavelength) have been traditionally viewed as positively interacting with a semiconductor material, as well as some of which energies/wavelengths/frequencies being traditionally viewed as not really causing any positive (or negative) results. In this regard, it has been previously viewed by the prior art, for example, that some incident light within, for example, the photoreactive portion of the solar spectrum does not have sufficient energies to form an electron-hole pair and in such cases these photons may simply pass through the solar cell without any positive or negative interactions with the solar cell. Additionally, it has also been traditionally believed that some photons have too much energy and simply can not interact completely with the solar cell material (e.g., there may be some interactions, but the interaction may be incomplete or that not all of the energy of the photon is used by the solar cell).

It is known, for example, that one band gap energy that can be made to exist in doped crystalline silicon is about 1.1 eV (1.1 electron volts). This amount of energy is known as an amount of energy which is required, for example, to free a bound electron to become a freely flowing electron which can be involved in the flow of a current. It has been believed historically that photons having more energy than what is required to free an electron may simply not utilize all of the energy to free an electron and such excess energy is simply lost; whereas it has also been believed that photons that do not have enough energy to free an electron to become involved in the flow of a current simply do not interact at all with the semiconductor material. Thus, it has been believed historically that photons within, for example, the photoreactive portion of the solar spectrum having less than required amounts of energy or more than required amounts of energy (as discussed above) do not interact in a positive or a negative way and such non-interaction has been traditionally blamed as being responsible for the loss of the effectiveness (e.g., in some cases about 70-90%) of the radiation or sunlight energy which is incident on a solar cell. Some approaches to increase the efficiency of solar cells in utilizing the photoreactive portion of the solar spectrum have suggested reducing the required band gap energy to a smaller number by utilizing an appropriate combination of dopants, but there is unfortunately a negative impact associated with such approaches. Particularly, the amount of band gap energy that can be designed into a solar cell substrate material (e.g., crystalline silicon) is limited, because, even though a small band gap may result in the production of more electrons, the traditional view would be that because more photons could be utilized, the width of the band gap also determines the strength of the electric field. Accordingly, if the band gap is too small, even though extra current is provided by the ability of a material, in theory, to absorb more photons and thus promote more electrons to a conduction band, the power output of the cell is lowered because a much smaller voltage is produced. In this regard, power is the multiplied effect of voltage times current (i.e., P=VI). In attempting to balance the two effects of current and voltage, one ideal band gap width for silicon has been determined to be about 1.4 eV (1.4 electron volts) for a cell made from a single material suitably doped.

However, the prior art has not recognized some very important negative effects which impact adversely on the power output of a solar photovoltaic cell. As discussed above, the historical view has been that when incident photons within, for example, the photoreactive portion of the solar spectrum, are of too low an energy, the incident photons do not positively interact with the solar cell semiconductor material; and when photons within, for example, the photoreactive portion of the solar spectrum are of too high an energy, some of the energy may be caused to interact with the solar cell semiconductor material and some of the energy of the photon is simply lost and does not take part in the interaction. However, what all prior art approaches fail to recognize is that there are negative power effects or negative consequences that can result when energies, specifically, incident frequencies or wavelengths within the photoreactive portion of the solar spectrum, which do not specifically match, for example, the band gap energies present in the semiconductor material. In this regard, the most efficient or highest output from a solar cell would occur when those energies which impart desirable effects (e.g., the controlled excitation of an electron and/or electron hole pair) are applied to (e.g., light incident upon) a photovoltaic material. For example, since light waves are comprised of photons that have been traditionally represented by a wave, when waves or frequencies (i.e., energies according to Equation 1) do not match (e.g., do not match directly or indirectly or are not harmonics of and/or are not heterodynes of particular energies) with the particular energies required to, for example, generate an electron/hole pair (e.g., promote electrons to the conductor band) the particular component wave or frequency of light within the photoreactive portion of the solar spectrum incident on the solar cell actually may detract or interfere with the production of power from a solar cell (e.g., desirable interactions with photons or waves of light may be at least partially, or substantially completely, offset by negative interactions).

Moreover, it should also be clear that positive or desirable effects include, but are not limited to, those effects resulting from an interaction (e.g., heterodyne, resonance, additive wave, subtractive wave, partial or complete constructive interference or partial or complete destructive interference) between a wavelength or frequency of incident light and a wavelength (e.g., atomic and/or molecular, etc.), frequency or property (e.g., Stark effects, Zeeman effects, etc.) inherent to the substrate itself. Accordingly, by providing substantially only those energies (i.e., wavelengths and frequencies) of light within the photoreactive portion of the solar spectrum required to cause desirable excitations in the solar cell photovoltaic materials (e.g., the formation of electron/hole pairs) the entire solar cell actually becomes more efficient. In some cases it may be difficult, if not impossible, to provide only those energies which provide desirable interactions, however, if as many undesirable energies as possible within the photoreactive portion of the solar spectrum can be blocked, eliminated and/or modified prior to contacting the solar cell photovoltaic material, then the power output of the solar cell should be enhanced. This approach is contrary to the prior art approaches which have attempted to design semiconductor materials such that they may interact directly, or through, for example, various light trapping approaches, with an even broader spectrum of available light energies within the photoreactive portion of the solar spectrum without regard to limiting particular “negative” light energies within the photoreactive portion of the solar spectrum from being incident on the solar cell substrates (e.g., limiting incident energies to those partial energy levels (frequency and wavelength) that can result in desirable outputs from the solar cells without any substantial undesirable interactions occurring, due to, for example, utilizing energies of light within the photoreactive portion of the solar spectrum which actually interfere with the production of power).

Accordingly, the present invention satisfies the long felt need in the solar cell industry to render solar cells more efficient by recognizing that it is not desirable for all wavelengths of light within any particular spectrum of light (e.g., natural sunlight) to be incident upon a solar cell photovoltaic substrate (e.g., crystalline silicon, amorphous silicon, single crystal silicon, cadmium sulfide, etc.) but rather to reduce or limit the incident light within the photoreactive portion of the solar spectrum to as many of those wavelengths as possible which can result in predominantly desirable interactions between the incident light and the solar cell's photovoltaic substrate (i.e., in other words, to reduce as many negative or destructively interfering wavelengths of light within the photoreactive portion of the solar spectrum as possible so as to reduce negative effects of, for example, destructive interference occurring in the photovoltaic substrate).

In this regard, there will be a particular combination of specific frequencies of light within the photoreactive portion of the solar spectrum (Note: light can be referred to by energy, wavelength and/or frequency, but for simplicity, will be referred to in these paragraphs immediately following primarily as “frequency” or “wavelength”) that will desirably interact with a solar cell's photovoltaic substrate. The particular frequencies of light within the photoreactive portion of the solar spectrum that should be caused to be incident upon a solar cell photovoltaic substrate should be as many of those frequencies as possible which can result in desirable effects (e.g., promoting electrons to a conduction band) within the substrate, while eliminating as many of those frequencies as possible which result in undesirable effects within the substrate. In this regard, certain frequencies will add energy to the photovoltaic material by, for example, causing atomic or molecular energies (e.g., electronic) to be provided; and certain frequencies of light will cause electrons to jump the band gap and/or form electron/hole pairs. It is important to note that virtually all of the desirable energies which can be applied to an appropriate photovoltaic substrate material can be calculated theoretically, or determined empirically. For example, if one knows the band gap width that is created within a semiconductor material due to, for example, the doping of the semiconductor with one or more suitable dopants, or the combination of band widths present in the material due to, for example, utilizing multiple suitable dopants, then those particular frequencies of light can be applied so that, for example, electron/hole pairs can be created and/or additional desirable energies can be imparted to, for example, electrons. For example, assuming arguendo that a band width created within a doped silicon semiconductor substrate required a wavelength of, for example, 600nm, to create an electron and/or electron/hole pair, then the application of a wavelength of light of about 600 nm would be a very desirable and very effective wavelength to apply. However, all harmonics of a wavelength of 600 nm would also be desirable (e.g., 1200, 1800, 300, 150, etc.). In addition, many heterodynes of 600 nm would be desirable (e.g., If the material has wavelengths 600 nm and 1000 nm, the subtractive heterodyne is 400 nm and the additive heterodyne is 1600 nm. In addition to the actual frequencies of the material, (i.e., 600 nm and 1000 nm), the heterodyne frequencies (i.e., 400 nm and 1600 nm), may also be beneficial). Additionally, in this example, while the exact wavelength of 600 nm would be the optimum wavelength to apply (as well as all those wavelengths corresponding to the exact harmonic and exact heterodyne wavelengths) wavelengths which are close to the 600 nm wavelength and thus that are close to the exact harmonic and/or close to the exact heterodyne wavelengths would also be desirable to apply. In this regard, FIG. 4 shows a typical bell-shaped curve “B” which represents a distribution of frequencies around the desired frequency fₒ.

FIG. 4 thus represents additional desirable frequencies that can be applied which do not correspond exactly to f₀, but are close enough to the frequency f₀ to achieve a desired effect. In particular, for example, those frequencies between and including the frequencies within the range of f₁ and f₂ would be most desirable. Note that f₁ and f₂ correspond to those frequencies above and below the resonant frequency f₀ wherein f₁, and f₂ correspond to about one half the maximum amplitude, aₘₐₓ, of the curve “B”. However, in practice, depending on the particular semiconductor material utilized, some frequencies slightly beyond those represented by the range of frequencies between f₁, and f₂ may also be desirable.

In addition to the harmonic and heterodyne frequencies (wavelengths) discussed above, particular energies which provide, for example, atomic or molecular energies (e.g., electronic) can also be permitted to interact with the photovoltaic substrate because providing such energies to the substrate material also is desirable in that energy is being transferred in a desirable manner to the photovoltaic substrate material.

Still further, in some instances certain blocks or regions of incident light may be desirable to prevent from contacting a photovoltaic material. In this regard, it may be desirable to block out complete portions of infrared wavelengths and/or complete portions of ultraviolet wavelengths to improve performance.

The precise combination of wavelengths or frequencies (and thus energies) that can be permitted to interact with solar cell photovoltaic substrates are important to determine, because essentially the desirable frequencies should be maximized, while the undesirable frequencies should be minimized.

There exist numerous theoretical and empirical means for determining desirable and undesirable frequencies (and thus energies) of incident light which should be obvious to those of ordinary skill in this art. In addition, there are numerous means for limiting undesirable frequencies incident upon a substrate material. Some of these different means are discussed later herein.

### BRIEF DESCRIPTION OF THE FIGURES

The following Figures are provided to assist in the understanding of the invention, but are not intended to limit the scope of the invention. Similar reference numerals have been used wherever in each of the Figures to denote like components; wherein

FIG. 1 is a general graphical representation of a typical output response of a crystalline silicon solar cell as a function of wavelength of incident sunlight.

FIG. 2 shows a sine wave which is representative of incident sunlight.

FIG. 3 shows a first desirable sine wave 1, a second undesirable sine wave 2 and a combination of the waves 1+2 showing both constructive and destructive interference effects.

FIG. 4 is a graphical representation depicting the bell-shaped curve of frequencies surrounding a particular representative desirable frequency of light f₀.

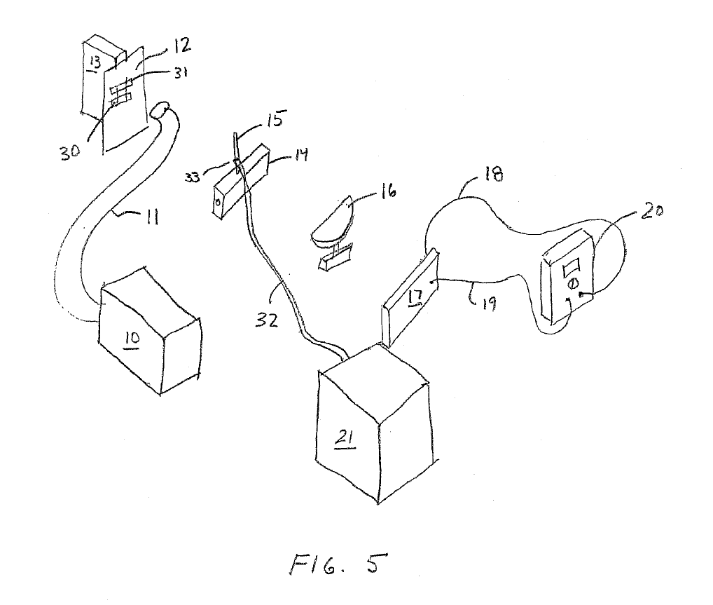

FIG. 5 shows a schematic in perspective view of an experimental setup utilized in Example 1 to selectively block a portion of the visible spectrum of light from being incident on a solar cell and thereafter measure the voltage and/or amperage output of the solar cell.

FIG. 6 shows a schematic of the spatial relationship which exists between portions of the set-up shown in FIG. 5.

FIGS. 7 and 8 are photographs which correspond to the schematic shown in FIG. 5 and the set-up used in Example 1.

### DETAILED DESCRIPTION OF THE INVENTION

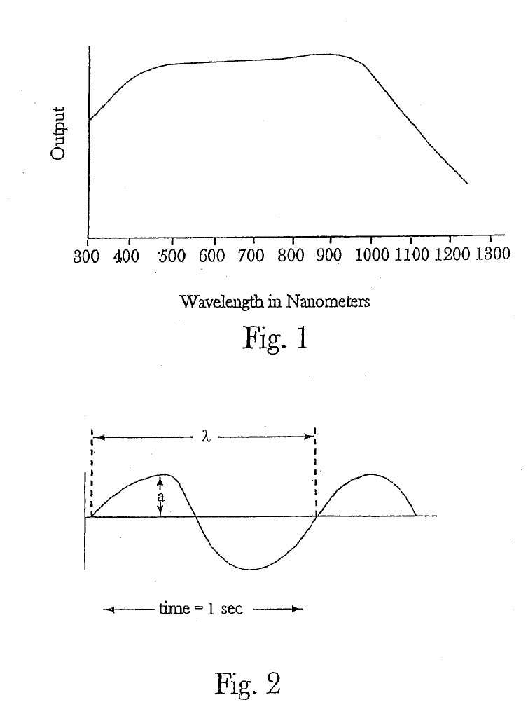

FIG. 1 shows a typical output response within the photoreactive portion of the solar spectrum for a crystalline silicon solar cell. In this regard, the x-axis corresponds to wavelengths from about 300 nanometers to about 1400 nanometers, which is about the typically desired response range within the photoreactive portion of the solar spectrum that traditional solar cell manufacturers have sought for the photovoltaic material(s) comprising the solar cell. The y-axis corresponds to a particular output present at various measured wavelengths along the x-axis. The prior art is replete with attempts to describe means for utilizing more and more of the wavelengths within the photoreactive portion of the solar spectrum (e.g., light trapping techniques, etc.), however, the prior art misses the point that undesirable effects can also occur at the same time that certain desirable effects are occurring resulting in a canceling or blocking out of some of the desirable effects.

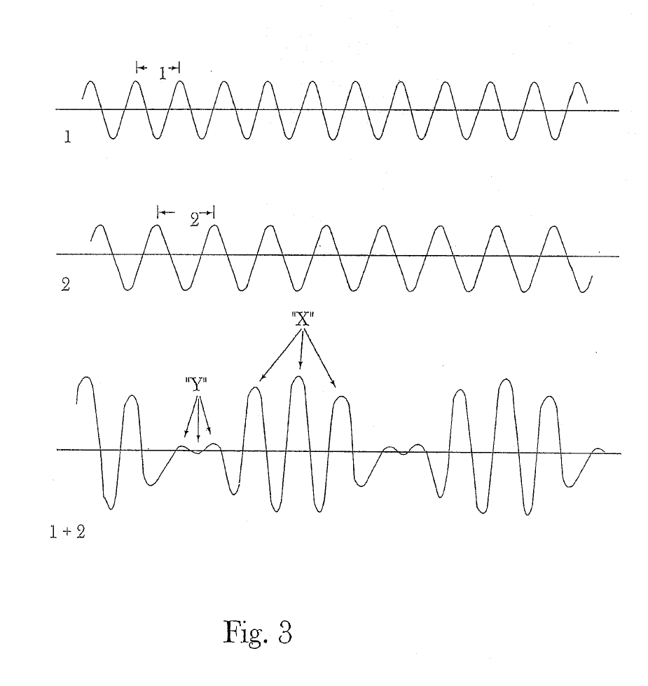

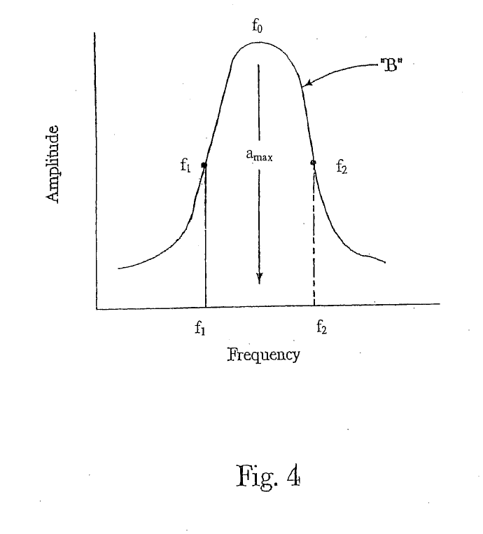

In this regard, for example, FIG. 2 shows a first sine wave which corresponds to a particular wavelength “λ”, a certain amplitude “a” and a frequency of 1 cycle per second “σ”. When the frequency of the sine wave matches perfectly, for example, the band gap energy in a semiconductor material, then substantially all of the energy in the sine wave is transferred into the creation of, for example, an electron/hole pair. However, when the frequency does not match exactly, the prior art believes that some of the energy may or may not be involved in desirable effects in the photovoltaic substrate material, but the prior art does not recognize that those frequencies which do not match desirable energy levels in a photovoltaic material actually may provide deleterious effects. These deleterious effects can be shown in, for example, FIG. 3.

FIG. 3 shows two different incident sine waves 1 and 2 which correspond to two different energies, wavelengths λ₁ and λ₂ (and thus different frequencies) of light (or photons) within the photoreactive portion of the solar spectrum which could be made to be incident upon the surface of a photovoltaic solar cell substrate material. Each of the sine waves 1 and 2 has a different differential equation which describes its individual motion. However, when the sine waves are combined into the resultant additive wave 1+2, the resulting complex differential equation, which describes the resultant combined energies, actually results in certain of the input energies being high (i.e., constructive interference) at certain points in time, as well as being low (i.e., destructive interference) at certain points in time.

In particular, assuming that the sine wave 1 corresponds to desirable incident energy within the photoreactive portion of the solar spectrum having a wavelength λ₁, which would result in positive or favorable effects if permitted to be incident on a solar cell substrate; and further assuming that the sine wave 2 corresponds to undesirable incident energy within the photoreactive portion of the solar spectrum having a wavelength λ₂, which would not result in positive or favorable effects if permitted to be incident on a solar cell substrate, then the resultant additive wave 1+2 shows some interesting characteristics. For example, the portions “X” represent areas where the two waves 1 and 2 have at least partially constructively interfered, whereas the portions “Y” represent areas where the two waves 1 and 2 have at least partially destructively interfered. Depending upon whether the portions “X” corresponds to desirable or undesirable wavelengths (i.e., resulting in positive or negative interactions with the substrate, respectively) then the portions “X” could enhance a positive effect in a substrate or could enhance a negative effect in a substrate. Similarly, depending on whether the portions “Y” correspond to desirable or undesirable wavelengths, then the portions “Y” may correspond to the effective loss of either a positive or negative effect.

It should be clear from this particular analysis that partial or complete constructive interferences (i.e., the points “X”) could maximize both positive and negative effects and that partial or complete destructive interferences “Y” could minimize both positive and negative effects. Accordingly, in this simplified example, by permitting predominantly desirable wavelengths λ₁ to be incident upon a semiconductor surface, the possibilities of negative effects resulting from the combination of waves 1 and 2 would be minimized or eliminated. In this regard, it is noted that in practice many desirable incident wavelengths within the photoreactive portion of the solar spectrum can be made to be incident on a surface of a photovoltaic substrate material. Moreover, it should also be clear that positive or desirable effects include, but are not limited to, those effects resulting from an interaction (e.g., heterodyne, resonance, additive wave, subtractive wave, partially or substantially complete constructive interference or partially or substantially complete destructive interference) between a wavelength or frequency of incident light and a wavelength (e.g., atomic and/or molecular, etc.), frequency or property (e.g., Stark effects, Zeeman effects, etc.) inherent to the substrate itself. Thus, by maximizing the desirable wavelengths (or minimizing undesirable wavelengths) within the photoreactive portion of the solar spectrum, solar cell efficiencies never before known can be achieved. Alternatively stated, certain destructive interference effects resulting from the combinations of different energies, frequencies and/or wavelengths can reduce the output in a solar cell photovoltaic substrate material. The present invention attempts to mask or screen as many of such undesirable energies (or wavelengths) as possible from becoming incident on the surface of a photovoltaic substrate and thus strive for, for example, the synergistic results that can occur due to, for example, desirable constructive interference effects between the incident wavelengths of light.

For example, it is known that glasses of various compositions can absorb (e.g., Pilkington's Ultraviolet—absorbing CMX glass) refract and/or reflect certain radiation which comes from the sun. Glasses can be manufactured so that they contain various elements in their structure that can absorb photons of particular energies (and thus wavelengths and frequencies) such that such absorbed energy does not find its way to a material (e.g., a photovoltaic substrate) located behind such glasses.

One exemplary empirical method to determine which wavelengths are the most desirable to be permitted to be incident upon a surface of a photovoltaic substrate utilize a concept related generally to that concept used in a tunable dye laser. Specifically, for example, a tunable die laser, generally, outputs multiple frequencies (or energies) of light from a laser source into a prism. The prism then separates or diffracts the multiple frequencies of light as an output. The multiple frequency output from the prism can then be selectively gated by an optical slit (e.g., a micrometer driven grating) which can be precisely positioned to permit transmission of only limited or desired frequencies therethrough. This selective positioning of the optical slit is what causes the laser to be tunable. By utilizing a device which uses one or more blocking portions (e.g., preferably a plurality) of blocking portions rather than an optical slit, wavelengths which are deleterious or undesirable for the performance of a solar cell can be determined. The blocking portions can be of any suitable height and width to achieve the desirable blocking of wavelengths of light.

Accordingly, once it is determined, either theoretically or empirically, which wavelengths within the photoreactive portion of the solar spectrum are the most desirable to be permitted to be incident upon a surface of a photovoltaic substrate material, then glass can be designed to, for example, absorb as many wavelengths of light as possible except for those wavelengths which result in positive interactions. In this regard, it is well known in the glass industry how to incorporate certain “impurities” into glasses to cause them to absorb various frequencies of light. Thus, the glass can be viewed simply as functioning as a filter (when added to an existing solar cell or panel (e.g., retrofitting) or inherently being part of the manufacture of a solar cell or solar panel when originally manufactured) which does not permit certain wavelengths of light within the photoreactive portion of the solar spectrum to pass therethrough, or rather, permit as many desirable wavelengths of light as possible to pass therethrough.

In addition, certain coatings can be placed directly upon an incident surface of a photovoltaic substrate material functioning as a solar cell to assist in blocking certain energies (or wavelengths or frequencies) of light within the photoreactive portion of the solar spectrum to be incident thereon. In this regard, there may be a need to produce a sandwich or layered structure of materials, for example, on a front surface of a solar cell photovoltaic substrate material such that the combination of materials actually serve to breakup or prevent certain light from being incident on a photovoltaic surface located behind the layered structure. Further, rather than merely capturing or absorbing undesirable light energies, it would be possible, through the use of, for example, certain physical structures, to cause certain wavelengths of light to be refracted, reflected or otherwise modified and minimize particular undesirable wavelengths, frequencies and/or energies to be incident on a surface of a solar cell photovoltaic substrate material.

Furthermore, certain monomer, oligimer, polymer and/or organometallic materials could also be desirable surface materials that could be used alone or in combination with, for example, certain glass materials in an attempt to achieve the goals of the invention, namely, to maximize particular desirable wavelengths, frequencies and/or energies within the photoreactive portion of the solar spectrum to be incident on a surface of a solar cell substrate material or, alternatively, to minimize particular undesirable wavelengths, frequencies and/or energies within the photoreactive portion of the solar spectrum from being incident on a surface of a solar cell substrate. Examples of such materials include a colored coating layer which may contain one or more dyes or pigments dispersed in one or more resin materials. Examples of dyes or pigments may include azo dyes, acridine dyes, nitro dyes, triphenylmethane dyes, azomethine dyes, xanthene dyes, indigiod dyes, benzo-and naphthoquinone dyes, anthraquinone dyes, mordant dyes, pyrazolone dyes, stilbene dyes, quinoline dyes, thiazole dyes, hydazone dyes, fluorescent dyes, cadmium yellow, molybdenum orange and red.

Examples of the binder resin used to contain the dye(s) may include polyacrylate resin, polysulfone resin, polyamide resin, acrylic resin, acrylonitrile resin, methacrylic resin, vinyl chloride resin, vinyl acetate resin, alkyd resin, polycarbonate, polyurethane, and nylon.

Moreover, in certain cases it may be desirable to utilize an iterative-type process, whereby certain solar cell materials are modified slightly in conjunction with the filtering or blocking and/or light refracting materials (e.g., at least one means for modifying incident sunlight prior to sunlight contacting the photovoltaic substrate) which are provided on at least one surface thereof. In this regard, it is well known that different dopants can be utilized in different semiconductor materials and that different dopants (or combinations of dopants) can result in different, for example, band gaps or band gap energy widths within a photovoltaic material, as well as different atomic or molecular energies (e.g., electronic which can be excited). Thus, it may be more advantageous to manufacture a particular type of photovoltaic substrate material to be used in conjunction with, for example, certain coverings and/or filters. The combination of the photovoltaic material and the covering and/or filtering material(s) may be different for different applications where the solar cells may experience, for example, higher or lower water contents in the atmosphere, higher or lower energies, higher or lower operating temperatures, etc., all of which factors can influence, for example, band gaps or energy levels within a photovoltaic substrate. All of such factors can be taken into account when designing a system such that the resultant system can provide the maximum effectiveness for the particular solar cells and/or solar panels. Moreover, in a similar regard, certain solar cell applications may find themselves in high temperature environments such as deserts, near the Equator, etc., whereby the operating temperature of the solar cells could be much higher relative, for example, the Arctic or Antarctic, outer space, etc. These higher temperatures can also influence energy levels within a photovoltaic substrate material. In addition, for example, photovoltaic materials located in outer space will, typically, be exposed to frequencies which are different from those frequencies which are incident on similar photovoltaic materials, located, for example, in the earth's atmosphere at sea level. In this regard, the particular combination of solar cell photovoltaic material and at least one means for modifying incident sunlight (e.g., a covering or filter material) may be different in one application or environment versus another. However, it is the goal of the invention that once the particular environment in which the solar cell is going to be operating in is understood, that the most desirable combination of solar cell substrate and covering or filter can be utilized in combination with each other.

### EXAMPLE 1

This Example demonstrates that the selected blocking of certain small groups or small portions of wavelengths or energies of visible light (e.g., blocking a portion of the photoreactive solar spectrum) can increase the output of a solar cell relative to unblocked visible light incident on the same solar cell. It should be understood that maximum output from solar cells will be achieved from blocking somewhat smaller and more numerous of wavelengths of the photoreactive portion of the visible spectrum but that this Example merely proves the general concept of the invention.

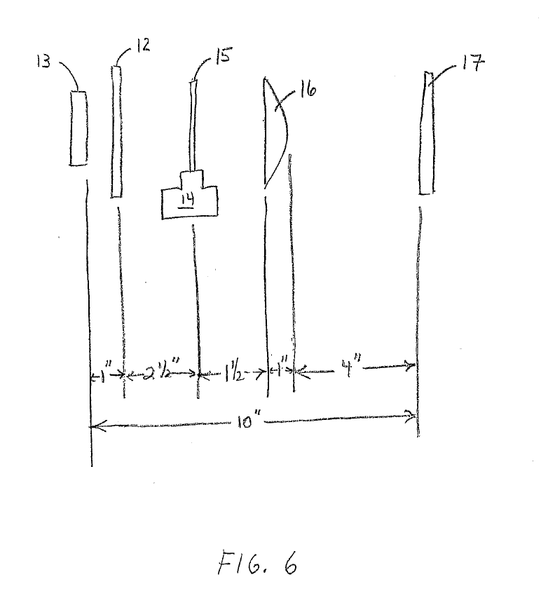

FIG. 5 shows a schematic of the experimental set-up used in accordance with this Example. A light source 10 known as an IMAGELITE™ from Stockard and Yale provided a suitable light spectrum that was transmitted through the flexible cable 11. The light emitted from the cable 11 was caused to be incident upon both of the separate slits 30 and 31 that were formed into a light opaque member 12. Each of the slits 30 and 31 were about ⅛″ in width (i.e., the vertical width of the horizontal opening). The light emitted from the light source 11 passed through the slits 30 and 31 and was caused to be incident upon a diffraction grating 13. In particular, the diffraction grating 13 was ruled and had a line density of about 1200 lines per millimeter, a blaze wavelength of about 350 nm, and had a peak efficiency of about 80% in the primary wavelength region of 200-1600 nm. The diffraction grating measured about 50×50×6 millimeters.

Once the light was emitted through the slits 30 and 31 and was caused to be incident upon the diffraction grating 13, the diffraction grating 13 caused the light to be split or diffracted into its components parts to form a spectrum (e.g., the colors of the rainbow) and the created spectrum was caused to be directed back through both slits 31 and 32 as a full color spectrum. The created full color spectra were directed toward a light blocking means 15 mounted upon an adjustable slide table 14. The spectrum that was transmitted toward the light blocking means 15 measured about 3 inches in horizontal length contiguous to the light blocking means 15 and was blocked by the horizontal width of the slits 31 and 32. The spectrum ran from purple (about 350 nm) to red (about 750 nm). The light blocking means 15 served to block selectively a portion of the emitted spectrum that was about 10 nm in total width (i.e., the light blocking means 15 selectively blocked various wavelengths about 10 nm in total width between about 350 nm and about 750 nm). The slide table 14, which selectively positioned the light blocking means 15, was positioned such that it was capable of physically moving the light blocking means 15 from the purple portion of the created spectrum all the way through the red portion of the created spectrum. The amount that the light blocking means 15 was moved for each measurement was approximately 11 nm, which approximately corresponded to its width of about 10 nm.

A spectrometer 21 was also attached to the movable light blocking means 15 by a flexible cable 32 and a detecting head 33. The detecting head 33 was caused to be in vertical alignment with the light blocking means 15 so as to be able to detect the wavelengths of light that were being blocked by the light blocking means 15 as the light blocking means 15 was selectively positioned to block various positions of the photoreactive portion of the visible spectrum.

Once a selected portion of the visible spectrum had been blocked with the light blocking means 15, the light (absent the blocked portion) was caused to be incident upon a condensing lens 16. The condensing lens 16 was obtained from Edmond Optics and had a 75 millimeter focal length. The condensed spectrum from the lens 16 was then caused to be incident upon a solar panel 17. The size of the spot of light incident on the solar panel was about 2 mm in diameter.

The solar panel 17 was obtained from a commercial source from a typical production run. The spot of light incident upon the solar panel 17 was caused to be incident on a non-collection portion of the solar panel 17 (i.e., the output from the lens 16 was caused to be incident upon a portion of the solar panel 17 which did not comprise an electrical collection grid). An Extech Instruments multimeter 20 was connected to the electrical conducting portions of the solar panel 17 through the electrodes 18 and 19. The output of the solar panel was then capable of being measured with the multimeter 20.

Table 1 shows a typical set of data that was generated by utilizing the experimental set-up shown in FIG. 5. In particular, the output from the solar panel was measured in micro-amps as a function of position of the light blocking means 15 at various locations in the spectrum generated through the slits 31 and 32. The first output readings of 4.0 micro-amps (measurements 1-5) correspond to the light blocking means 15 blocking a range of wavelengths from about 350 nm to about 404 nm in 10 nm sections or groups. Each subsequent reading corresponds to a movement of the light blocking means 15 of about 11 nm. Accordingly, it is clear that measurements 1-5 resulted in about a 4.0 micro-amps output. However, measurements 6-8 resulted in an increased output of about 4.1 micro-amps which corresponded to blocking wavelengths of 405-415 nm; 416-426 nm; and 427-437 nm, respectively. Further, measurement 21 showed an output from the solar cell increasing to about 4.5 micro-amps. Measurements 22 and 23 resulted in outputs of about 4.4 micro-amps, and so on.

TABLE 1

| MEASUREMENT | μAMP | WAVELENGTHS |
|---|---|---|
| NUMBER | OUTPUT | BLOCKED (nm) |
| 1 | 4.0 | 350-360 |
| 2 | 4.0 | 361-371 |
| 3 | 4.0 | 372-382 |
| 4 | 4.0 | 383-393 |
| 5 | 4.0 | 394-404 |
| 6 | 4.1 | 405-415 |
| 7 | 4.1 | 416-426 |
| 8 | 4.1 | 427-437 |
| 9 | 4.2 | 438-448 |
| 10. | 4.2 | 449-459 |
| 11 | 4.2 | 460-470 |
| 12 | 4.2 | 471-481 |
| 13 | 4.2 | 482-492 |
| 14 | 4.2 | 493-503 |
| 15 | 4.2 | 504-514 |
| 16 | 4.2 | 515-525 |
| 17 | 4.2 | 526-536 |
| 18 | 4.2 | 537-547 |
| 19 | 4.0 | 548-558 |
| 20 | 4.0 | 559-569 |
| 21 | 4.5 | 570-580 |
| 22 | 4.4 | 581-591 |
| 23 | 4.4 | 592-602 |
| 23 | 4.3 | 603-613 |
| 24 | 4.3 | 614-624 |
| 25 | 4.3 | 625-635 |
| 26 | 4.3 | 636-646 |
| 27 | 4.3 | 647-657 |
| 28 | 4.3 | 658-668 |
| 29 | 4.4 | 669-679 |
| 30 | 4.3 | 680-690 |
| 31 | 4.3 | 691-701 |
| 32 | 4.3 | 702-712 |
| 33 | 4.3 | 713-723 |
| 34 | 4.3 | 724-734 |
| 35 | 4.3 | 735-745 |

These experimental data show, in a crude manner, that the blocking of at least a portion of the photovoltaic reactive portion of a solar spectrum can result in an enhanced output from the solar cell.

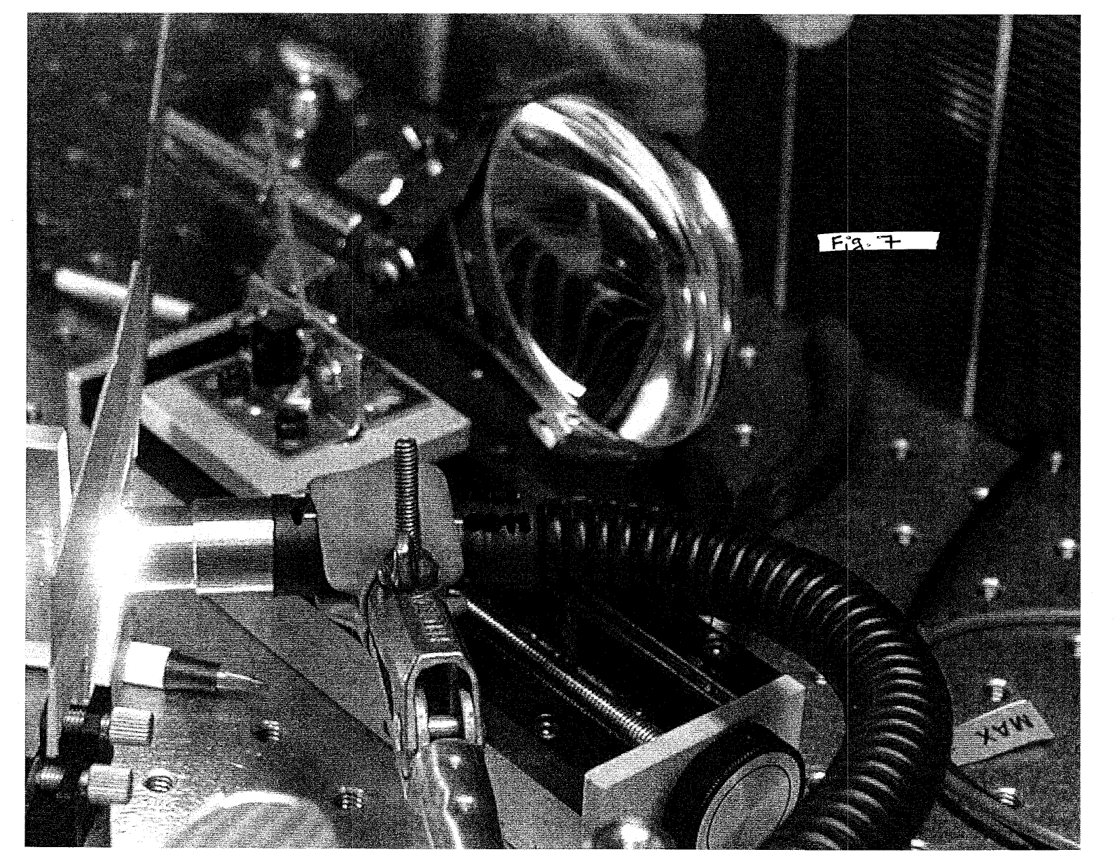

The approximate distances between each of the optical members and the solar cell shown in FIG. 5 is shown in FIG. 6. In particular, the distance between the light blocking means 15 and the opaque member 12 is about 2½ inches. The distance between the light blocking means 15 and the front of the condensing lens 16 is about 1½ inches. The distance from the back of the condensing lens 16 and the solar cell 17 is about 4 inches. The approximate horizontal width of the visible spectrum which projected at the light blocking means 15 is about 3 inches. The width of the light blocking means 15 was about 1/16 of an inch. Accordingly, the amount of light blocked by the light blocking means 15 was about 10 nm at any point that the light blocking means was positioned within the created spectrum.

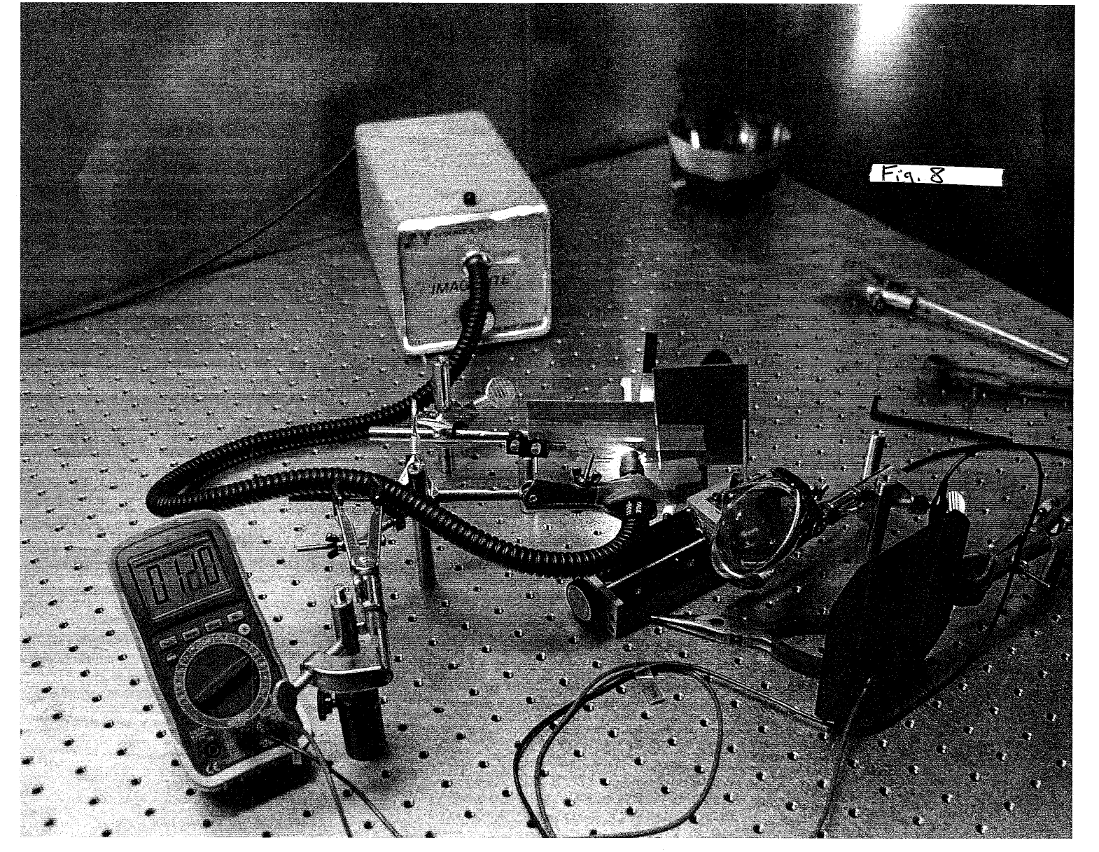

FIGS. 7 and 8 correspond to actual photographs of the experimental set-up shown in FIG. 5.

While there has been illustrated and described what is at present considered to be the preferred embodiments of the present invention, it will be understood by those skilled in the art that various changes and modifications may be made, and equivalents may be substituted for elements thereof without departing from the true scope of the invention. In addition, many modifications may be made to adapt the teachings of the invention to a particular situation without departing from the central scope of the invention. Therefore, it is intended that this invention not be limited to the particular embodiments disclosed as the best mode contemplated for carrying out this invention, but that the invention will include all embodiments falling within the scope of the appended claims.

1. A device for producing the flow of electrons due to solar energy being incident thereon comprising:
at least one solar cell photovoltaic substrate material comprising at least one primary band gap and: (1) at least one primary frequency, (2) at least one harmonic frequency and (3) at least one heterodyne frequency of sunlight associated therewith, wherein said photovoltaic substrate material generates electron flow responsive to a photoreactive portion of the solar spectrum; and
at least one means for modifying at least a portion of the photoreactive portion of the solar spectrum of sunlight, said at least one means being positioned between said at least one solar cell substrate material and incident sunlight containing said photoreactive portion, whereby said at least one means maximizes the incidence of constructively interfering frequencies of light within the photoreactive portion of the solar spectrum, which correspond to: (1) said at least one primary frequency, (2) said at least one harmonic frequency and (3) said at least one heterodyne frequency.

2. The device of claim 1, wherein said at least one means for modifying at least a portion of the photoreactive portion of the solar spectrum from sunlight comprises at least one material.

3. The device of claim 2, wherein said at least one material comprises at least one cover material which covers at least a portion of at least one surface of said at least one solar cell photovoltaic substrate material.

4. The device of claim 1, wherein said at least one substrate material comprises at least one semiconductor material.

5. The device of claim 4, wherein said at least one semiconductor material comprises at least one material selected from the group consisting of amorphous silicon, crystalline silicon and cadmium sulfide.

6. The device of claim 1, wherein said at least one means for modifying comprises at least one filter.

7. The device of claim 1, wherein said constructively interfering frequencies of light within the photoreactive portion of the solar spectrum comprise those frequencies which are distributed symmetrically about said at least one harmonic frequency and which comprise those frequencies which correspond to more than half of the maximum amplitude associated with said at least one harmonic frequency.

8. The device of claim 1, wherein said constructively interfering frequencies of light within the photoreactive portion of the solar spectrum comprise those frequencies which are distributed symmetrically about said at least one heterodyne frequency and which comprise those frequencies which correspond to more than about one-half of the maximum amplitude associated with said at least one heterodyne frequency.

9. A method of increasing the efficiency of a solar cell photovoltaic substrate material, said solar cell photovoltaic substrate material comprising at least one primary band gap comprising:
determining at least one set of constructively interfering energies occurring within at least a portion of the photoreactive portion of the solar spectrum, said at least one set of constructively interfering energies correspond to at least one primary frequency, at least one harmonic frequency and at least one heterodyne frequency associated with said at least one primary band gap, which photoreactive portion, when applied to a solar cell photovoltaic substrate material, results in the promotion of electrons to a conduction band, said conduction band being an inherent characteristic of said solar cell photovoltaic material;
determining at least one means for filtering sunlight, such that said at least one means for filtering maximizes the amount of constructively interfering energies which correspond to: (1) said at least one primary frequency; (2) said at least one harmonic frequency and (3) said at least one heterodyne frequency, being incident on said solar cell material; and
combining said at least one substrate material and said at least one means for filtering sunlight together to permit constructively interfering incident frequencies of light within said photoreactive portion of the solar spectrum to be incident upon the solar cell photovoltaic substrate.

10. A method for determining constructively interfering energies from at least a portion of the photoreactive portion of the solar spectrum for a solar cell photovoltaic substrate material comprising:
determining at least one primary band gap width present in said solar cell substrate material;
determining at least one primary frequency of light corresponding in energy to said at least one primary band gap width; and
determining at least one harmonic and at least one heterodyne of said at least one primary frequency of light within the photoreactive portion of the solar spectrum, whereby substantially all of said constructively interfering energies corresponding to said determined at least one primary and said determined at least one harmonic and at least one heterodyne are determined.

11. The method of claim 10, wherein all desirable harmonics and all desirable heterodynes of said at least one primary frequency of light are determined.

12. The device of claim 1, wherein said photoreactive portion of the solar spectrum comprises wavelengths of light from about 300 nanometers to about 1400 nanometers.

13. The method of claim 9, wherein said photoreactive portion of the solar spectrum comprises wavelengths of light from about 300 nanometers to about 1400 nanometers.

14. The method of claim 10, wherein said photoreactive portion of the solar spectrum comprises wavelengths of light from about 300 nanometers to about 1400 nanometers.

15. The method of claim 9, wherein said constructively interfering energies from at least a portion of the photoreactive portion of the solar spectrum comprise desirable frequencies, such desirable frequencies being those desirable frequencies which are distributed symmetrically about a primary frequency which corresponds in energy to at least one primary band gap width, said desirable frequencies including substantially all of those frequencies which correspond to more than about one-half of the maximum amplitude associated with said primary frequency.

16. The method of claim 9, wherein said at least one means for filtering sunlight means comprises at least one filter.

17. The method of claim 9, wherein said constructively interfering energies within the photoreactive portion of the solar spectrum comprise those frequencies which are distributed symmetrically about said at least one primary frequency and which correspond to more than about one-half of the maximum amplitude associated with said at least one primary frequency.
